(19) United States
(12) Patent Application Publication
(10) Pub. No.: US 2025/0392323 A1
(43) Pub. Date: Dec. 25, 2025

(54) APPARATUS AND METHOD FOR CONVERTING DIGITAL SIGNAL INTO ANALOG SIGNAL

(71) Applicant: Korea Advanced Institute of Science and Technology, Daejeon (KR)

(72) Inventors: Shinhyun CHOI, Daejeon (KR); Taehwan JANG, Daejeon (KR); See-On PARK, Daejeon (KR); Hakcheon JEONG, Daejeon (KR)

(21) Appl. No.: 19/244,825

(22) Filed: Jun. 20, 2025

(30) Foreign Application Priority Data
Jun. 21, 2024 (KR) 10-2024-0081029

(51) Int. Cl. H03M 1/80; H03M 1/66

(52) U.S. Cl. CPC H03M 1/808; H03M 1/662

(57) ABSTRACT

There is provided a method for an apparatus for converting a digital signal into an analog signal, comprising: a weight adjustment unit, configured to adjust a weight of a digital signal having an arbitrary bit order; a conversion unit, configured to output a variable resistance value based on a result of adjusting the weight; and an output unit, configured to output a current signal having a magnitude corresponding to the result based on the resistance value.

### TECHNICAL FIELD

The disclosure relates to a technology for converting a digital signal into an analog signal, and more particularly, to a technology capable of replacing an conventional digital-to-analog converter (hereinafter referred to as a DAC). This work was supported by National Research Foundation of Korea (NRF) grant funded by the Korea government (Ministry of Science and ICT) (Project unique No.: 2710086334; Project No.: RS-2025-04162969; R&D project: Research and Development Project: Next-generation intelligent semiconductor technology development (R&D)—New material resource technology development; Research Project Title: Development of Monolithic Stacked Neuron-Synapse Co-Integrated Hardware for Implementing 1,000 TOPS/W-Class High-Performance Neuromorphic Computing; and Project period: 2025.04.01.˜2027.12.31.), National Research Foundation of Korea (NRF) grant funded by the Korean government (Ministry of Science and ICT) (Project unique No.: 2710079351; Project No.: RS-2025-00555433; R&D project: Individual Basic Research (Ministry of Science and Technology) (R&D); Research Project Title: Development of next-generation PUF system based on high-stability ultra-low-power array utilizing novel single-device ReRAM-PRAM hybrid characteristics; and Project period: 2025.03.01.˜2028.02.29.), and Korea Institute for Advancement of Technology grant funded by the Korea government (Ministry of Trade, Industry and Energy) (Project unique No.: 2410010853; Project No.: KI002692; R&D project: Industrial Innovation Talent Growth Support (R&D); Research Project Title: Support for Graduate School of Semiconductor Specialization (Korea Advanced Institute of Science and Technology); and Project period: 2025.03.01.˜2026.02.28.).

This application claims priority to Korean Patent Application No. 10-2024-0081029, filed on Jun. 21, 2024, the entirety of which is incorporated herein by reference for all purposes.

### BACKGROUND ART

A general DAC is a functional block that performs signal conversion in a digital-to-analog domain within a mixed signal system.

A digital signal is composed of a series of binary numbers with weights. In order to distinguish these weights, a DAC is composed of passive devices such as a resistor and a capacitor, and an operational amplifier (op-amp). In this case, when a bit resolution of a digital signal increases in order to process a high-precision signal, the number of passive devices required by the DAC increases exponentially.

Since the passive devices occupy a significant amount of area in ICs due to manufacturing process constraints, the increase in the bit resolution of the digital signal leads to the increase in the area of the DAC. In addition, an operational amplifier, which is another component of the DAC, has an internal circuit composed of dozens of transistors, which leads to larger chip area and static power consumption.

The large area and energy problems of the DAC are considered as major problems in miniaturization and power reduction of chips in the IC design of the mixed signal system.

The above-described background art is technical information that the inventor possessed for the derivation of the present invention or acquired in the course of deriving the present invention, and therefore cannot necessarily be regarded as publicly known prior art disclosed to the general public before the filing of the present invention.

### SUMMARY

The present disclosure is directed to providing a digital-to-analog conversion technology that operates as a single device by using dynamic characteristics of resistive switching without using conventional passive devices and operational amplifiers.

However, the problem to be solved by the present disclosure is not limited to that mentioned above, and other problems to be solved that are not mentioned may be clearly understood by those of ordinary skill in the art to which the present disclosure belongs from the following description.

In accordance with an embodiment of the present invention, there is provided an apparatus for converting a digital signal into an analog signal, comprising: a weight adjustment unit, configured to adjust a weight of a digital signal having an arbitrary bit order; a conversion unit, configured to output a variable resistance value based on a result of adjusting the weight; and an output unit, configured to output a current signal having a magnitude corresponding to the result based on the resistance value.

The conversion unit may include a resistive switching device.

The conversion unit may further include an analog signal output multiplexer for outputting the resistance value as a single signal, and one terminal of the resistive switching device may be connected to the analog signal output multiplexer, and the other terminal of the resistive switching device may be connected to a ground terminal.

The output unit may include a current mirror circuit.

The current mirror circuit may include a first metal oxide semiconductor field effect transistor (MOSFET) connected to an output terminal of the analog signal output multiplexer; and a second MOSFET connected to a gate terminal of the first MOSFET. Here, a voltage magnitude of the gate terminal may change depending on the resistance value, the second MOSFET may output, through an output terminal of the second MOSFET, the current signal whose magnitude varies according to the voltage magnitude, in a form of an analog signal.

The magnitude of the current signal may be adjusted depending on voltage magnitudes of the first MOSFET and the second MOSFET.

The weight adjustment unit may include a digital signal input multiplexer, wherein the digital signal input multiplexer may be configured to apply the digital signal to the conversion unit in a form of a voltage pulse.

The weight adjustment unit may be configured to adjust the result from a set pulse of a least significant bit (LSB) of the digital signal to a set pulse of a most significant bit (MSB) of the digital signal.

The result may include an application time or magnitude of a voltage adjusted by the weight adjustment unit.

In accordance with an embodiment of the present invention, there is provided an apparatus for converting a digital signal into an analog signal, comprising: a weight adjustment unit, configured to adjust a weight of a digital signal having an arbitrary bit order; a conversion unit, configured to output a variable resistance value based on a result of adjusting the weight; and an output unit, configured to output a current signal having a magnitude corresponding to the result based on the resistance value.

The conversion unit may include a plurality of resistive switching devices coupled in parallel in an array form.

The conversion unit may further include an analog signal output multiplexer for outputting the resistance value as a single signal. Here, one terminal of the resistive switching device may be connected to the analog signal output multiplexer, and the other terminal of the resistive switching device may be connected to a ground terminal.

In accordance with an embodiment of the present invention, there is provided a method for converting a digital signal into an analog signal using a digital-to-analog conversion apparatus, comprising: adjusting, by the digital-to-analog conversion apparatus, a weight of the digital signal, when a digital signal having an arbitrary bit order is input to the digital-to-analog conversion apparatus; outputting, by the digital-to-analog conversion apparatus, a variable resistance value based on a result of adjusting the weight; and outputting, by the digital-to-analog conversion apparatus, a current signal having a magnitude corresponding to the result based on the resistance value.

The outputting the variable resistance value may include outputting the variable resistance value based on the result by using a resistive switching device.

The outputting of the current signal may include adjusting a magnitude of the current signal according to a change in a magnitude of the variable resistance value by using a current mirror circuit.

The magnitude of the current signal may be adjusted depending on voltage magnitude of a MOSFET included in the current mirror.

The adjusting the weight may include applying the digital signal to the resistive switching device in a form of a voltage pulse.

The adjusting of the weight may further include adjusting the result from a set pulse of a least significant bit (LSB) of the digital signal to a set pulse of a most significant bit (MSB) of the digital signal

In accordance with an embodiment of the present invention, there is provided a non-transitory computer-readable storage medium storing a computer program, wherein the computer program includes instructions for causing a processor to perform a method for converting a digital signal into an analog signal in a digital-to-analog conversion apparatus, the method comprising: adjusting a weight of the digital signal, when a digital signal having an arbitrary bit order is input; outputting a variable resistance value based on a result of adjusting the weight; and outputting a current signal having a magnitude corresponding to the result based on the resistance value.

In accordance with an embodiment of the present invention, there is provided a computer program stored in a non-transitory computer-readable storage medium, wherein the computer program includes instructions for causing a processor to perform a method for converting a digital signal into an analog signal in a digital-to-analog conversion apparatus, the method comprising: adjusting a weight of the digital signal, when a digital signal having an arbitrary bit order is input; outputting a variable resistance value based on a result of adjusting the weight; and outputting a current signal having a magnitude corresponding to the result based on the resistance value.

According to an embodiment of the present disclosure, by implementing the digital-to-analog conversion technology with the transistor and the resistive switching device without passive devices such as resistors and capacitors, it is possible to scale the digital-to-analog conversion apparatus to the nano-sized dimensions. In addition, since there is no change in the circuit even if the bit resolution increases and the amount of current flowing through the resistive switching device decreases depending on the scaling, it is possible to implement an energy-efficient, ultra-small digital-to-analog conversion apparatus. In addition, it is expected that the area efficiency may be maximized when implementing the multi-channel digital-to-analog conversion apparatus by expanding the resistive switching device of the digital-to-analog conversion apparatus according to the present disclosure into an array form.

### BRIEF DESCRIPTION OF THE DRAWINGS

FIG. 1 is a block diagram for illustrating a function of an apparatus for converting a digital signal to an analog signal (hereinafter, digital-to-analog conversion apparatus) according to an embodiment of the present disclosure.

FIG. 2A and FIG. 2B are diagrams exemplarily illustrating the digital signal input to the digital-to-analog conversion apparatus of FIG. 1, and the stimulus applied to the resistive switching device.

FIG. 3 is a readout circuit diagram for specifically illustrating the function of the digital-to-analog conversion apparatus according to an embodiment of the present disclosure.

FIG. 4 is a circuit diagram for illustrating in detail a function of a digital-to-analog conversion apparatus according to another embodiment of the present disclosure.

FIGS. 5 to 7 are experimental result graphs comparing the operation results in various bit resolution environments using the digital-to-analog conversion apparatus according to an embodiment of the present disclosure.

FIGS. 8 to 10 illustrate a display driving circuit utilizing the digital-to-analog conversion apparatus according to different embodiments of the present disclosure.

FIG. 11 is a graph showing a multi-channel DAC operation utilizing the resistive switching device array according to an embodiment of the present disclosure.

### DETAILED DESCRIPTION OF THE INVENTION

The advantages and features of the embodiments and the methods of accomplishing the embodiments will be clearly understood from the following description taken in conjunction with the accompanying drawings. However, embodiments are not limited to those embodiments described, as embodiments may be implemented in various forms. It should be noted that the present embodiments are provided to make a full disclosure and also to allow those skilled in the art to know the full range of the embodiments. Therefore, the embodiments are to be defined only by the scope of the appended claims.

In describing embodiments of the present invention, if it is considered that a detailed description of a known function or configuration may unnecessarily obscure the gist of the present invention, the detailed description will be omitted. In addition, the terms described below are terms defined in consideration of functions in the embodiments of the present invention, the terms may vary according to the intention or precedent of a technician working in the field, the emergence of new technologies, and the like. Therefore, the terms used in the present disclosure should be defined based on the meaning of the terms and the overall contents of the present disclosure, not just the name of the terms.

The mixed signal system to which the digital-to-analog conversion apparatus according to the embodiment of the present disclosure may be applied refers to a system in which digital technology and analog technology are coupled to process signals. The mixed signal system is widely used in electronic devices and systems such as communications, audio, displays, medical equipment, embedded systems, and analog computing. The integrated circuit for implementing the mixed signal system is composed of many functional blocks such as an analog signal input/output device, a digital signal processor, and a converter that serves as to convert signals in the analog domain and the digital domain. Since the miniaturization, low power, and high performance of the mixed signal system integrated circuit are directly related to the economic efficiency of the integrated circuit, researches on the miniaturization, low power, and high performance of the mixed signal system integrated circuit are actively being conducted.

Meanwhile, a resistive switching device applied to a digital-to-analog conversion apparatus according to the embodiment of the present disclosure refers to a device whose resistance changes due to external stimuli such as voltage and heat, and has advantages such as low power and high integration. The resistive switching device has dynamic characteristics in which the resistance changes, enabling the implementation of the system, which is implemented in the existing transistor-based system in a complex manner, with a small area and low energy consumption.

Therefore, since the digital-to-analog conversion operation may be performed with a single device and thus there is no change in the circuit due to the increase in the bit resolution of the digital signal, a digital-to-analog conversion apparatus based on the resistive switching device according to an embodiment of the present disclosure is suitable for the miniaturization and power reduction of the digital-to-analog conversion apparatus. The present disclosure proposes such a digital-to-analog conversion apparatus based on a resistive switching device, thereby reducing the area and energy occupied by the digital-to-analog conversion apparatus in the mixed signal system integrated circuit, and achieving the miniaturization and power reduction of the mixed signal system integrated circuit.

The digital-to-analog conversion apparatus based on the resistive switching device proposed in the present disclosure may convert a digital signal into an analog signal through two steps as follows.

First, the digital signal to be converted is applied to the resistive switching device in the form of the voltage pulse (set pulse) to set the resistance state of the resistive switching device depending on the magnitude of the digital signal (digital signal application time).

Second, the voltage for reading the resistance of the resistive switching device is applied to the resistive switching device to output an analog value (analog signal output time).

The digital-to-analog conversion apparatus based on the resistive switching device proposed in the present disclosure may be largely composed of three parts as follows.

First, the stimulus applied to the resistive switching device is adjusted depending on the bit order of the digital signal in order to convert the digital signal into the analog signal without distortion.

Second, a readout circuit for reading a physical quantity of the resistive switching device is configured without an operational amplifier.

Third, the multi-channel digital-to-analog conversion apparatus is implemented in the form of a resistive switching device array.

Hereinafter, an embodiment of the present disclosure will be described in detail with reference to the attached drawings.

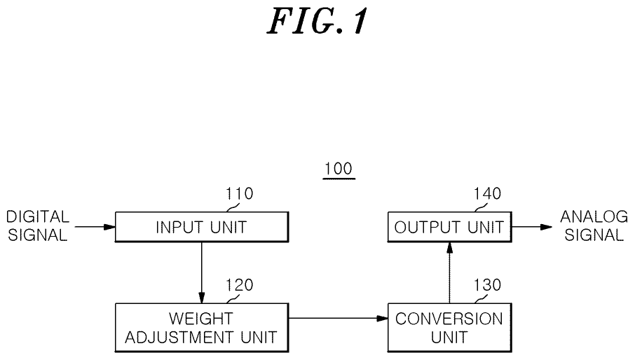

FIG. 1 is a block diagram illustrating a function of an apparatus for converting a digital signal to an analog signal 100 (hereinafter, digital-to-analog conversion apparatus) according to an embodiment of the present disclosure.

As illustrated in FIG. 1, a digital-to-analog conversion apparatus 100 may include an input unit 110, a weight adjustment unit 120, a conversion unit 130, and an output unit 140.

The input unit 110 may input a digital signal having an arbitrary bit order, and the weight adjustment unit 120 may adjust a weight of the input digital signal. As described below, the weight adjustment unit 120 may be composed of a voltage source and a multiplexer, and an adjusted voltage (a voltage whose time or magnitude is adjusted) for the input digital signal may be applied to the conversion unit 130.

The conversion unit 130 may generate a variable resistance value based on the result of the weight being adjusted through the weight adjustment unit 120. The conversion unit 130 is one of core elements of the digital-to-analog conversion apparatus 100 according to the embodiment of the present disclosure, and may include, for example, a resistance conversion element.

In order to convert the digital signal into the analog signal, the influence of the input of the digital signal on the output of the analog signal should vary depending on the bit order of the digital signal.

To this end, the weight adjustment unit 120 of the digital-to-analog conversion apparatus 100 according to an embodiment of the present disclosure adjusts a pulse application time or magnitude from a set pulse indicating a least significant bit (LSB) of the digital signal applied to the resistive switching device described below to a set pulse of a most significant bit (MSB). Since the degree of resistance change of the resistive switching device varies depending on the application time or magnitude of the input voltage, by using the pulse application method, the influence on the resistive switching of the resistive switching device may vary depending on the bit order of the digital signal.

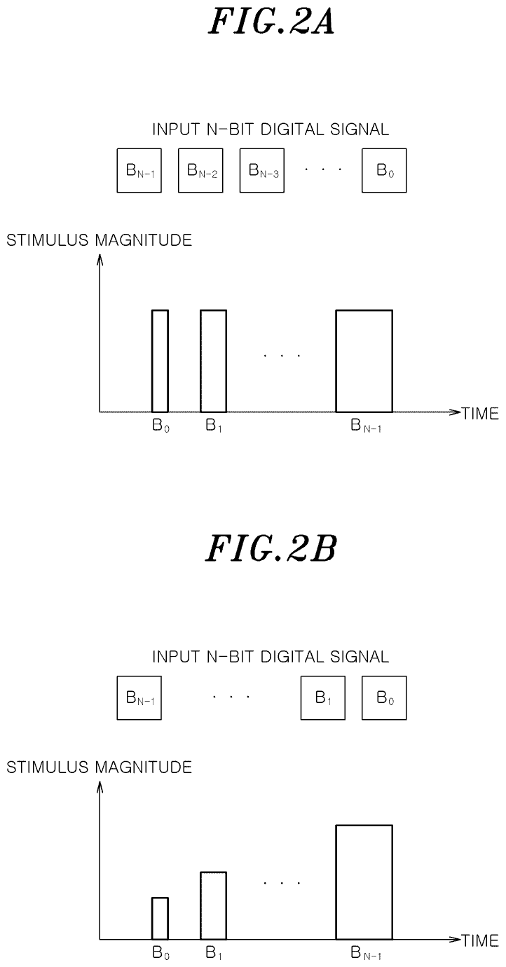

FIGS. 2A and 2B are diagrams illustrating an example of such a pulse application method, and are diagrams exemplarily illustrating a digital signal input to the digital-to-analog conversion apparatus 100 of FIG. 1 and a stimulus applied to the resistive switching device.

First, FIG. 2A illustrates that a pulse application time from a set pulse indicating a first applied LSB to a set pulse indicating a last applied MSB gradually increases, thereby causing different effects on the resistive switching device depending on the bit order. Next, FIG. 2B illustrates that a stimulus magnitude of the pulse from the set pulse indicating the first applied LSB to the set pulse indicating the last applied MSB changes, thereby causing different effects on the resistive switching device depending on the bit order.

The present disclosure proposes a digital-to-analog conversion apparatus based on a resistive switching device that may distinguish a bit order of an input digital signal in a single device by using such a pulse application method.

When the digital-to-analog conversion apparatus is implemented in this manner, even if the bit resolution of the digital input signal increases, the bit resolution of the digital-to-analog conversion apparatus may increase by increasing the number of set pulses. For this reason, the digital-to-analog conversion apparatus based on the resistive switching device proposed in the present invention exhibits no change in its circuit configuration with the increase in the bit resolution.

Meanwhile, the output unit 140 may output a current signal (analog signal) having a magnitude corresponding to the result of adjusting the weight of the weight adjustment unit 120 based on the resistance value generated by the resistive switching device of the conversion unit 130.

In order to output the analog signal from the resistive switching device having conductivity corresponding to the input digital signal, the readout circuit is required. According to an embodiment of the present disclosure, in order to efficiently implement the digital-to-analog conversion apparatus based on the resistive switching device in terms of the area and energy, it is proposed that the readout circuit of the resistive switching device is configured as a current mirror.

Hereinafter, the circuit configuration of the digital-to-analog conversion apparatus 100 according to an embodiment of the present disclosure together with the current mirror will be described.

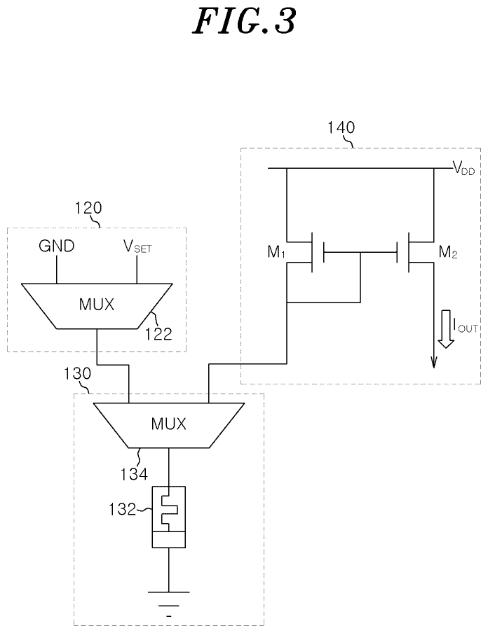

FIG. 3 is a readout circuit diagram for specifically illustrating the function of the digital-to-analog conversion apparatus 100 according to an embodiment of the present disclosure, and the digital-to-analog conversion apparatus 100 according to an embodiment of the present disclosure may include the weight adjustment unit 120, the conversion unit 130, and the output unit 140.

As illustrated in FIG. 3, the weight adjustment unit 120 may include a digital signal input multiplexer 122 for applying the digital signal to the conversion unit 130 in the form of a voltage pulse.

The digital signal input multiplexer 122 is equipped with a ground (GND) and a voltage set pulse terminal, and may be connected to the conversion unit 130 described later.

The conversion unit 130 may include a resistive switching device 132 according to an embodiment of the present disclosure and an analog signal output multiplexer 134.

One terminal of the resistive switching device 132 may be connected to the analog signal output multiplexer 134, and the other terminal of the resistive switching device 132 may be connected to the ground terminal.

In addition, the analog signal output multiplexer 134 may be connected to the digital signal input multiplexer 122 of the weight adjustment unit 120 and the output unit 140.

The conversion unit 130 having these configurations may generate a variable resistance value (a resistance value that varies depending on the voltage application time and magnitude) based on the result of adjusting the weight of the digital signal, and the generated resistance value may be applied to the output unit 140.

The output unit 140 may include a current mirror circuit, and the current mirror circuit may include a first MOSFET M₁ connected to an output terminal of the analog signal output multiplexer 134 and a second MOSFET M₂ connected to a gate terminal of the first MOSFET M₁.

The output unit 140 may output a current signal whose magnitude changes in the form of the analog signal through the output terminal of the second MOSFET M₂ by changing the voltage magnitude of the gate terminal depending on the resistance value applied from the conversion unit 130.

Here, the magnitude of the current signal may be adjusted depending on the voltage magnitude of the first MOSFET M₁ and the second MOSFET M₂.

In the readout circuit of FIG. 3, the magnitude of the current flowing through the first MOSFET M₁ varies depending on the resistance of the resistive switching device 132. That is, as the magnitude of the digital signal input to the resistive switching device 132 increases, the resistive switching device 132 has a smaller resistance, so the current flowing through the first MOSFET M₁ decreases and a gate voltage magnitude of the current mirror changes accordingly. At an output terminal of the current mirror, a current having a magnitude corresponding to the digital signal input to the resistive switching device 132 flows, thereby outputting the analog signal in the form of the current. In addition, a current mirror-based readout circuit proposed in the present disclosure may control a magnitude of an output current IOUT by controlling sizes of transistors of the first MOSFET M₁ and the second MOSFET M₂ constituting the current mirror, so it is possible to amplify or attenuate the analog signal output by the digital-to-analog conversion apparatus 100 based on the resistive switching device 132.

In this way, the digital-to-analog conversion apparatus 100 based on the resistive switching device proposed in the present disclosure configures the readout circuit as the current mirror, so, unlike the DAC using the conventional passive device and the operational amplifier, it is possible to implement the digital-to-analog conversion operation using only the transistor and the resistive switching device 132, and adjust the magnitude of the analog signal output.

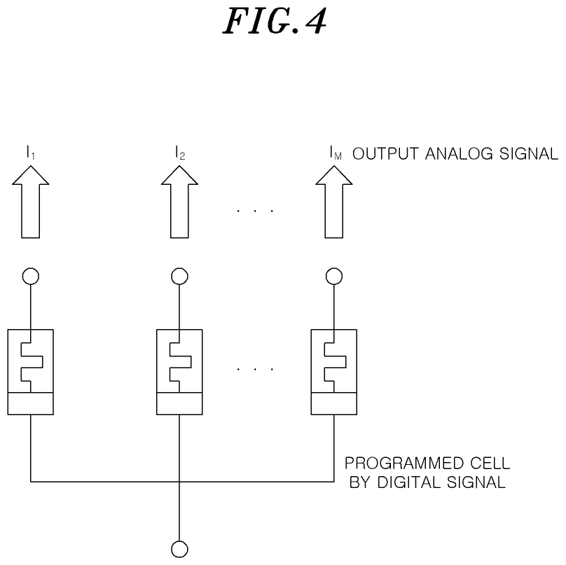

FIG. 4 is a circuit diagram for illustrating in detail a function of a digital-to-analog conversion apparatus 100 according to another embodiment of the present disclosure.

The circuit diagram of the digital-to-analog conversion apparatus 100 of FIG. 4 is characterized by implementing the resistive switching device 132 constituting the conversion unit 130 in the circuit diagram of the digital-to-analog conversion apparatus 100 of FIG. 3 as the multi-channel.

In applications requiring the digital-to-analog conversion apparatus 100 constituted as the multi-channel, a parallel digital-to-analog conversion operation is required, and the present disclosure proposes a method for implementing a digital-to-analog conversion operation with a resistive switching device in an array form.

The resistive switching device may be integrated in the array form due to its structural simplicity, and each cell inside the resistive switching device array may perform the digital-to-analog conversion operation.

FIG. 4 is a schematic diagram of the parallel digital-to-analog conversion operation using the resistive switching device array.

When the digital signal to be converted is input to each cell of the resistive switching device array during the digital signal application time, each cell is programmed in parallel depending on the incoming digital signal. During the analog signal output time, an analog current output is obtained from each cell of the programmed array.

As described above, the digital-to-analog conversion apparatus based on the resistive switching device proposed in the present disclosure may perform the parallel digital-to-analog conversion operation by integrating the resistive switching devices in the array form. In this way, the present disclosure may implement the digital-to-analog conversion apparatus for the applications requiring the multi-channel digital-to-analog conversion operation, such as analog computing and a display driver, in a small area.

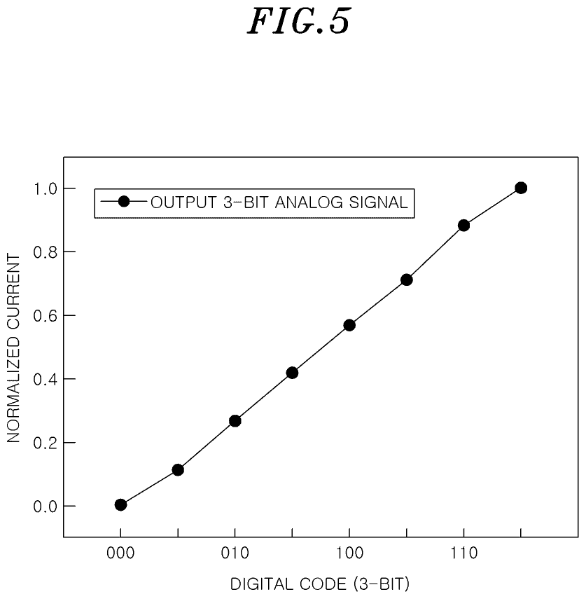

FIGS. 5 to 7 are experimental result graphs comparing the operation results in various bit resolution environments using the digital-to-analog conversion apparatus according to an embodiment of the present disclosure.

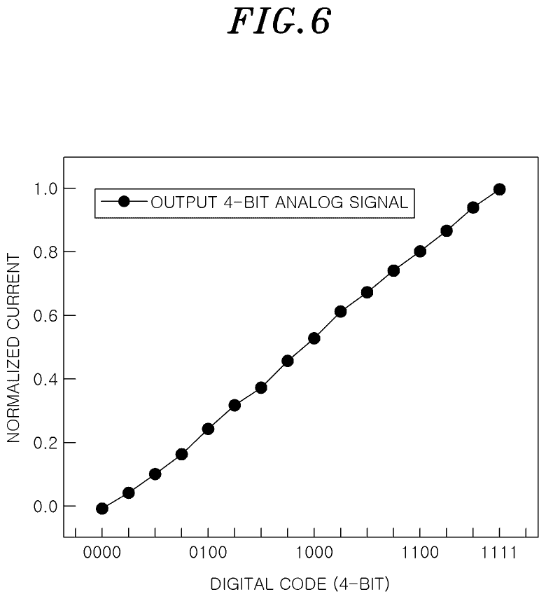

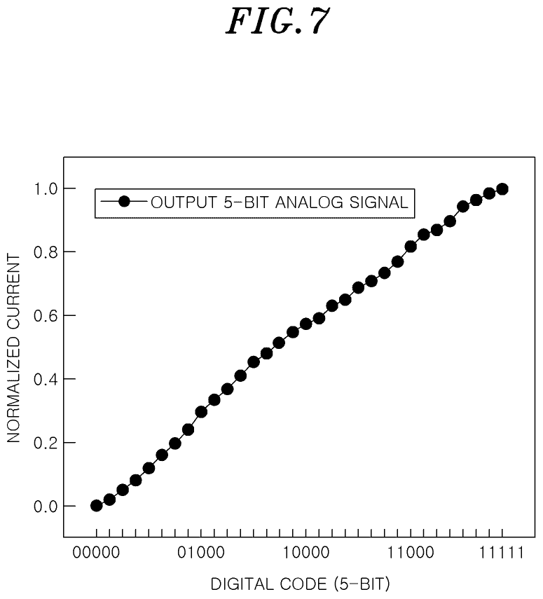

FIGS. 5 to 7 illustrate the results of converting a digital signal having a bit resolution of 3 bits (FIG. 5), 4 bits (FIGS. 6), and 5 bits (FIG. 7) into an analog signal in the form of a current using the digital-to-analog conversion apparatus based on the resistive switching device proposed in the present disclosure.

This experiment was conducted by applying a stimulus corresponding to a digital signal to a single resistive switching device as proposed in the configuration of the invention, and then applying a reading voltage to the resistive switching device to measure the current flowing through the resistive switching device.

While the bit resolution increased from 3 bits to 5 bits, the digital-to-analog conversion operation was performed in the same resistive switching device without additional circuit modifications, except for adjusting the number of stimulus pulses applied to the resistive switching device.

Through the above experiment, it is shown that the digital-to-analog conversion apparatus based on the resistive switching device proposed in the present disclosure may achieve a very small size and low energy consumption without requiring circuit modifications as the bit resolution increases.

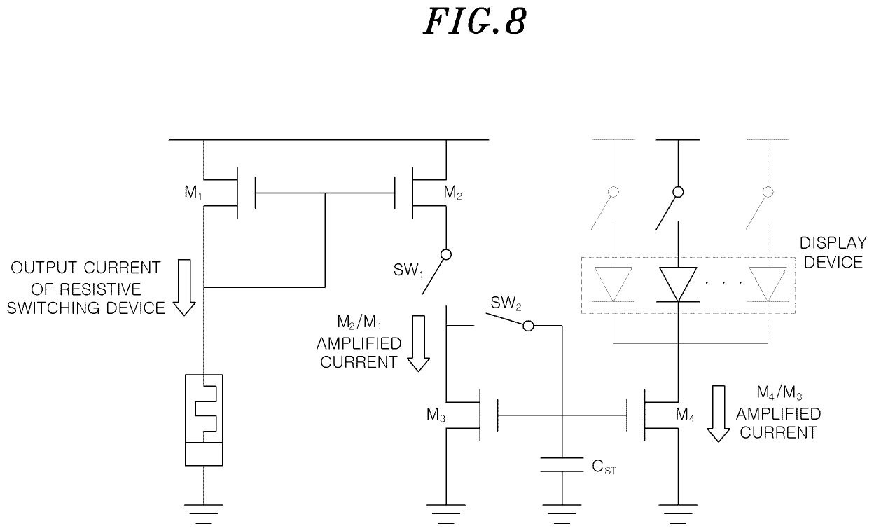

FIGS. 8 to 10 illustrate a display driving circuit utilizing the digital-to-analog conversion apparatus according to different embodiments of the present disclosure.

The display driving circuit according to an embodiment of the present disclosure may include a circuit that receives an output current of the resistive switching device-based DAC as an input, amplifies, or attenuates the output circuit, and then transmits a signal to a display device (e.g., a light-emitting diode, a liquid crystal display, etc.).

FIG. 8 illustrates the display driving circuit utilizing the digital-to-analog conversion apparatus according to an embodiment of the present disclosure. The display driving circuit of FIG. 8 may include a first current mirror composed of M₁ and M₂, a second current mirror composed of M₃ and M₄, and a plurality of current control switches SW1 and SW2.

First, the current output from the resistive switching device-based DAC may pass through the first current mirror. In this case, the current may be amplified or attenuated depending on a current ratio of M₂/M₁ and output to a drain of M₂.

Next, the SW1 and SW2 switches are closed so that the output current of the first current mirror may be charged to a capacitor C_{ST}. Thereafter, after a predetermined time has elapsed, the same current as M₂ may flow through M₃.

Next, by sequentially opening the SW2 and SW1 switches, the charge stored in C_{ST} is isolated, and a current adjusted depending on a current ratio of M₄/M₃ may flow through M₄. In this case, as the output current of M₄ is applied to the light-emitting element, the light-emitting element may emit light with a predetermined brightness.

In this way, as the two-stage current mirror structure is applied, the current generated by the resistive switching device may be effectively amplified or attenuated, so the targeted current level may be provided to the light-emitting element.

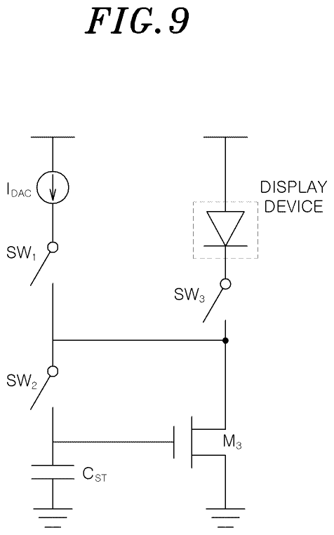

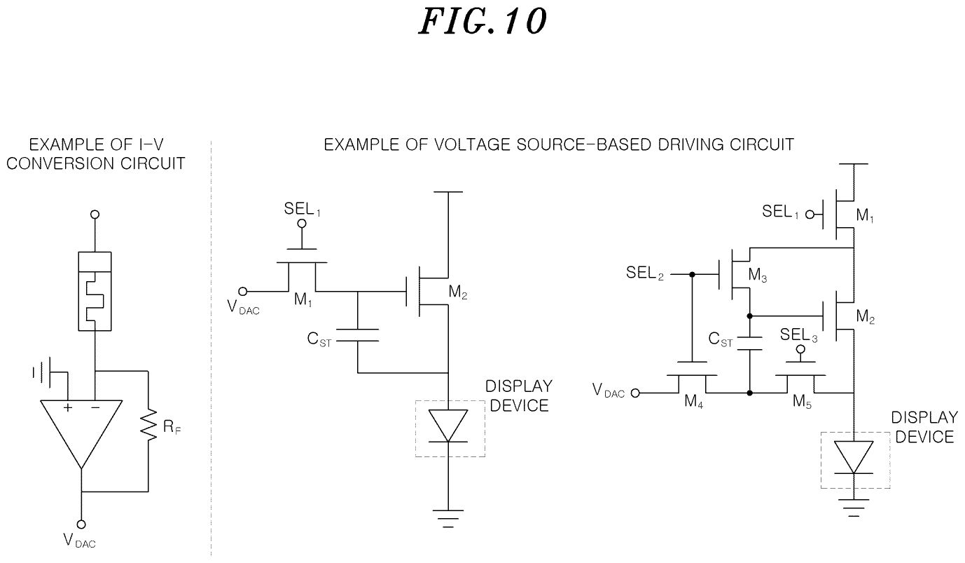

FIGS. 9 and 10 illustrate the display driving circuit utilizing the digital-to-analog conversion apparatus according to another embodiment of the present disclosure. Specifically, FIG. 9 illustrates a current source-based display driving circuit that directly applies a current to the display device through the resistive switching device-based DAC and a selection switch. In addition, FIG. 10 illustrates a voltage source-based display driving circuit that converts the output of the resistive switching device-based DAC into a voltage signal through an I-V conversion circuit and then drives the display device.

The above-described display driving circuits are described as examples for the convenience of understanding and are not limited thereto. That is, the display driving circuit utilizing the digital-to-analog conversion apparatus according to the present disclosure may change depending on a current or voltage range of the display device, and may be flexibly changed and applied according to the actual implementation environment.

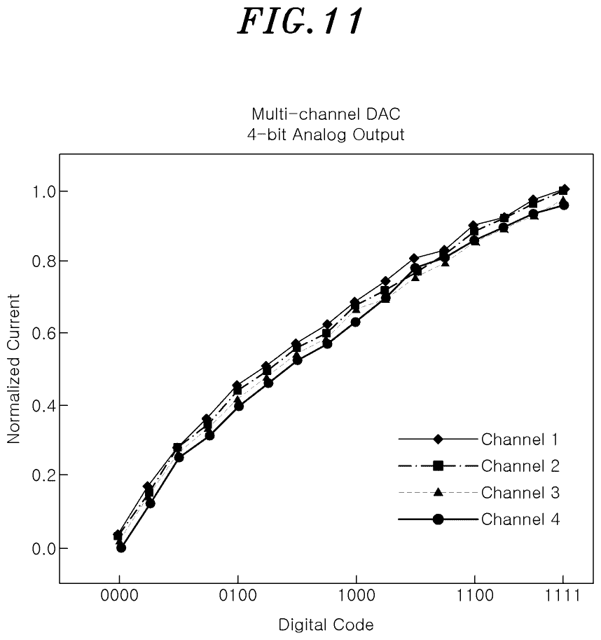

FIG. 11 is a graph showing a multi-channel DAC operation utilizing the resistive switching device array according to an embodiment of the present disclosure.

The multi-channel DAC operation of FIG. 11 was performed using the circuit structure illustrated in FIG. 4, and referring to FIG. 11, it may be seen that a multi-channel DAC function is implemented in which each resistive switching device in the resistive switching device array adjusts an analog signal output according to the digital input.

As described above, according to an embodiment of the present disclosure, by implementing the digital-to-analog conversion technology with the transistor and the resistive switching device without passive devices such as resistors and capacitors, it is possible to scale the digital-to-analog conversion apparatus to the nano-sized dimensions. In addition, since there is no change in the circuit even if the bit resolution increases and the amount of current flowing through the resistive switching device decreases depending on the scaling, it is possible to implement an energy-efficient, ultra-small digital-to-analog conversion apparatus. In addition, it is expected that the area efficiency may be maximized when implementing the multi-channel digital-to-analog conversion apparatus by expanding the resistive switching device of the digital-to-analog conversion apparatus according to the present disclosure into an array form.

The application fields, marketability, etc., that may be expected through the digital-to-analog conversion apparatus according to an embodiment of the present disclosure are as follows.

First, since the mixed signal system is used throughout modern information processing devices such as communications, audio, displays, medical equipment, and embedded systems, and most DACs are essential components in the mixed signal system, the digital-to-analog conversion apparatus based on the resistive switching device proposed in the present disclosure is expected to have a very wide range of applications. In particular, the digital-to-analog conversion apparatus based on the resistive switching device according to the embodiment of the present disclosure may easily implement the digital-to-analog conversion apparatus as the multi-channel by integrating resistive switching devices in the array form, and since the digital-to-analog conversion apparatus may be scaled to nano-sized dimensions, the digital-to-analog conversion apparatus is expected to be suitable for applications such as analog computing, mobile display drivers, and nanobio applications.

In addition, most modern information processing devices use the mixed signal system to process the digital signal and the analog signal together. Since the miniaturization and power reduction of the integrated circuits for implementing the mixed signal system are directly related to the economic efficiency of the integrated circuits, it is expected that the weight reduction of the mixed signal system through the energy-efficient, ultra-small digital-to-analog conversion apparatus proposed in the present disclosure will bring about a great economic effect.

In particular, recently, the demand for mobile devices such as laptops, smartphones, and tablets has been rapidly increasing, and many attempts have been made to drive the display driving circuit (hereinafter referred to as DDI) of these mobile devices at low power due to the limitations of the battery capacity of the mobile devices. The DAC requires a large area and energy, especially in the DDI. When the digital-to-analog conversion apparatus based on the resistive switching device according to an embodiment of the present disclosure is used, it is expected that the DDI with a small area and energy efficiency may be designed. The development of the novel digital-to-analog conversion technology is expected to provide significant economic benefits in the DDI field, which currently forms a vast market.

The nanobio medical field, which is another application area of the digital-to-analog conversion apparatus based on the resistive switching device, is expected to revolutionize medical technology by enabling the diagnosis of pathogens or genetic diseases at the molecular level using nano-sized medical devices. The scale of the biosensor market for disease diagnosis has been continuously increasing, and it is expected to reach approximately $16 billion by 2030. When a nano-sized medical device capable of both diagnosis and treatment is developed by integrating a biosensor with the digital-to-analog conversion apparatus based on the resistive switching device proposed in the present disclosure, significant economic benefits are anticipated.

Combinations of steps in each flowchart attached to the present disclosure may be executed by computer program instructions. Since the computer program instructions can be mounted on a processor of a general-purpose computer, a special purpose computer, or other programmable data processing equipment, the instructions executed by the processor of the computer or other programmable data processing equipment create a means for performing the functions described in each step of the flowchart.

The computer program instructions can also be stored on a computer-usable or computer-readable storage medium which can be directed to a computer or other programmable data processing equipment to implement a function in a specific manner. Accordingly, the instructions stored on the computer-usable or computer-readable recording medium can also produce an article of manufacture containing an instruction means which performs the functions described in each step of the flowchart.

The computer program instructions can also be mounted on a computer or other programmable data processing equipment. Accordingly, a series of operational steps are performed on a computer or other programmable data processing equipment to create a computer-executable process, and it is also possible for instructions to perform a computer or other programmable data processing equipment to provide steps for performing the functions described in each step of the flowchart.

In addition, each step may represent a module, a segment, or a portion of codes which contains one or more executable instructions for executing the specified logical function(s). It should also be noted that in some alternative embodiments, the functions mentioned in the steps may occur out of order. For example, two steps illustrated in succession may in fact be performed substantially simultaneously, or the steps may sometimes be performed in a reverse order depending on the corresponding function.

What is claimed is:

1. An apparatus for converting a digital signal into an analog signal, comprising:
a weight adjustment unit, configured to adjust a weight of a digital signal having an arbitrary bit order;
a conversion unit, configured to output a variable resistance value based on a result of adjusting the weight; and
an output unit, configured to output a current signal having a magnitude corresponding to the result based on the resistance value.

2. The apparatus of claim 1, wherein the conversion unit includes a resistive switching device.

3. The apparatus of claim 2, wherein the conversion unit further includes an analog signal output multiplexer for outputting the resistance value as a single signal, and
wherein one terminal of the resistive switching device is connected to the analog signal output multiplexer, and the other terminal of the resistive switching device is connected to a ground terminal.

4. The apparatus of claim 3, wherein the output unit includes a current mirror circuit.

5. The apparatus of claim 4, wherein the current mirror circuit includes:
a first metal oxide semiconductor field effect transistor (MOSFET) connected to an output terminal of the analog signal output multiplexer; and
a second MOSFET connected to a gate terminal of the first MOSFET, and
wherein a voltage magnitude of the gate terminal changes depending on the resistance value,
wherein the second MOSFET outputs, through an output terminal of the second MOSFET, the current signal whose magnitude varies according to the voltage magnitude, in a form of an analog signal.

6. The apparatus of claim 5, wherein the magnitude of the current signal is adjusted depending on voltage magnitudes of the first MOSFET and the second MOSFET.

7. The apparatus of claim 1, wherein the weight adjustment unit includes a digital signal input multiplexer, wherein the digital signal input multiplexer is configured to apply the digital signal to the conversion unit in a form of a voltage pulse.

8. The apparatus of claim 7, wherein the weight adjustment unit is configured to adjust the result from a set pulse of a least significant bit (LSB) of the digital signal to a set pulse of a most significant bit (MSB) of the digital signal.

9. The apparatus of claim 8, wherein the result includes an application time or magnitude of a voltage adjusted by the weight adjustment unit.

10. The apparatus of claim 1, wherein the conversion unit includes a plurality of resistive switching devices coupled in parallel in an array form.

11. A method for converting a digital signal into an analog signal using a digital-to-analog conversion apparatus, comprising:
adjusting, by the digital-to-analog conversion apparatus, a weight of the digital signal, when a digital signal having an arbitrary bit order is input to the digital-to-analog conversion apparatus;
outputting, by the digital-to-analog conversion apparatus, a variable resistance value based on a result of adjusting the weight; and
outputting, by the digital-to-analog conversion apparatus, a current signal having a magnitude corresponding to the result based on the resistance value.

12. The method of claim 11, wherein the outputting the variable resistance value includes outputting the variable resistance value based on the result by using a resistive switching device.

13. The method of claim 12, wherein the outputting of the current signal includes adjusting a magnitude of the current signal according to a change in a magnitude of the variable resistance value by using a current mirror circuit.

14. The method of claim 13, wherein the magnitude of the current signal is adjusted depending on voltage magnitude of a MOSFET included in the current mirror.

15. The method of claim 12, wherein the adjusting the weight includes applying the digital signal to the resistive switching device in a form of a voltage pulse.

16. The method of claim 15, wherein the adjusting of the weight further includes adjusting the result from a set pulse of a least significant bit (LSB) of the digital signal to a set pulse of a most significant bit (MSB) of the digital signal

17. A non-transitory computer-readable storage medium storing a computer program,
wherein the computer program includes instructions for causing a processor to perform a method for converting a digital signal into an analog signal in a digital-to-analog conversion apparatus,
the method comprising:
adjusting a weight of the digital signal, when a digital signal having an arbitrary bit order is input;
outputting a variable resistance value based on a result of adjusting the weight; and
outputting a current signal having a magnitude corresponding to the result based on the resistance value.

18. The method of claim 17, wherein the outputting the variable resistance value includes outputting the variable resistance value based on the result by using a resistive switching device.

19. The method of claim 18, wherein the outputting of the current signal includes adjusting a magnitude of the current signal according to a change in a magnitude of the variable resistance value by using a current mirror circuit.

20. The method of claim 19, wherein the magnitude of the current signal is adjusted depending on voltage magnitude of a MOSFET included in the current mirror.
